(19) United States
(12) Patent Application Publication
(10) Pub. No.: US 2025/0146120 A1
(43) Pub. Date: May 8, 2025

(54) EVAPORATION MASK AND METHOD FOR EVALUATING EVAPORATION MASK

(71) Applicant: DARWIN PRECISIONS CORPORATION, Hsinchu County (TW)

(72) Inventor: CHI-WEI LIN, Hsinchu County (TW)

(21) Appl. No.: 18/809,370

(22) Filed: Aug. 20, 2024

(30) Foreign Application Priority Data
Nov. 6, 2023 (TW) 112142694

(51) Int. Cl. C23C 14/04; C23C 14/24; H10K 71/16

(52) U.S. Cl. CPC C23C 14/042; C23C 14/24; H10K 71/166

(57) ABSTRACT

An evaporation mask includes an outer frame and a sub-mask. The outer frame is provided with an opening, and both sides of the opening are provided with two opposite positioning side edges. The sub-mask is adapted to be connected to the outer frame and is provided with a pattern area and two fixed areas. The pattern area is located at a center of the sub-mask. A surface of the sub-mask is provided with a first datum point and a second datum point. The first datum point is located at a center of the pattern area. The second datum point is located at an edge, close to one of the fixed areas, of the pattern area. A first distance between the first datum point and the second datum point is less than or equal to 200 μm. A method for evaluating the evaporation mask is also provided.

### FIELD OF THE INVENTION

The present invention relates to an evaporation mask and a method for evaluating the evaporation mask, and more particularly relates to an evaporation mask and a method for evaluating the evaporation mask used for manufacturing a display panel.

### BACKGROUND OF THE INVENTION

An organic light-emitting diode (OLED) display panel is a common display assembly for a current portable electronic device and has many advantages such as self-illumination, a wide viewing angle, high energy efficiency, short response time, lightness, and thinness. With the market development of portable electronic devices and increasing display quality, the OLED display panel has received attention gradually.

A common manufacturing mode for the OLED display panel includes: manufacturing a plurality of sub-masks with through-holes first; then, welding the sub-masks to the same screen frame to manufacture a fine metal mask (FMM); and then, in an evaporation process, covering a glass substrate with the FMM and depositing a material on the glass substrate to manufacture a light-emitting pattern on the display panel. In the process, conditions such as shape and welding quality of the sub-masks of the FMM all affect the shape, size, and distribution of the light-emitting pattern on the glass substrate and affect the display quality of the OLED display panel.

### SUMMARY OF THE INVENTION

The present invention provides an evaporation mask with a good shape, which can avoid the problem of diffused evaporation in the process of producing a display panel.

The present invention also provides a method for evaluating the evaporation mask. By applying the evaluated evaporation mask in the process of producing the display panel, the problem of diffused evaporation can be avoided.

To achieve the above advantages, an embodiment of the present invention provides an evaporation mask, including an outer frame and a sub-mask. The outer frame is provided with an opening, and both sides of the opening are provided with two opposite positioning side edges. The sub-mask is adapted to be connected to the outer frame and is provided with a pattern area and two fixed areas. The pattern area is located at a center of the sub-mask. The two fixed areas are located on two opposite sides of the pattern area and are adapted to be respectively connected to the two positioning side edges when the sub-mask is connected to the outer frame. A surface of the sub-mask is provided with a first datum point and a second datum point. The first datum point is located at a center of the pattern area. The second datum point is located at an edge, close to one of the fixed areas, of the pattern area. A first distance between the first datum point and the second datum point is less than or equal to 200 μm in a thickness direction of the sub-mask.

In an embodiment, there is a second distance between the second datum point and the adjacent fixed area in an interval direction perpendicular to the thickness direction, and the second distance is greater than or equal to 20 mm.

In an embodiment, a protruding section is formed on the sub-mask, and the protruding section is located between the first datum point and the fixed area.

In an embodiment, there is a plurality of welding points between the sub-mask and the outer frame, and the fixed area is encircled by the welding points.

In an embodiment, the welding points are arranged as a plurality of lines, and the welding points in different lines are staggered.

In an embodiment, a thickness of the sub-mask is between 150 μm and 500 μm.

In an embodiment, the pattern area is provided with a plurality of through-holes passing through the sub-mask in a thickness direction of the sub-mask.

In an embodiment, in the thickness direction, the surface is at least one of an evaporation surface and a back surface. The through-holes include a first opening located in the back surface, a second opening located in the evaporation surface, and a neck opening located between the first opening and the second opening. An opening sectional area of the second opening is larger than an opening sectional area of the neck opening.

In an embodiment, the first datum point and the second datum point are located next to the through-holes in the thickness direction.

An embodiment of the present invention provides a method for evaluating an evaporation mask. The evaporation mask includes an outer frame and a sub-mask. The outer frame is provided with an opening. Both sides of the opening are provided with two opposite positioning side edges. The sub-mask is adapted to be connected to the outer frame and is provided with a pattern area and two fixed areas. The pattern area is located at a center of the sub-mask. The two fixed areas are located on two opposite sides of the pattern area and are adapted to be respectively connected to the two positioning side edges when the sub-mask is connected to the outer frame. The method includes:
measuring positions of a first datum point and a second datum point on a surface of the sub-mask in a thickness direction of the sub-mask, the first datum point being located at a center of the pattern area and the second datum point being located at an edge, close to one of the fixed areas, of the pattern area; and
determining that the evaporation mask is qualified when a first distance between the first datum point and the second datum point is less than or equal to 200 μm.

According to the above description, for the evaporation mask provided by the present invention, because the height difference between the center and the edge of the pattern area subjected to welding and gravity is still smaller than a fixed value, when the glass substrate is evaporated, the mask fits the surface of the glass substrate as far as possible, so that the problem of diffused evaporation generated by the separation of the evaporation mask and the glass substrate is avoided. According to the method for evaluating the evaporation mask, because the evaporation mask evaluated qualified has the shape satisfying the evaporation mask, by applying the evaluated evaporation mask in the process of producing the display panel, the problem of diffused evaporation can be avoided.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

FIG. 1 is a schematic top diagram of an evaporation mask in an embodiment of the present invention;

FIG. 2 is a schematic partially enlarged diagram of the evaporation mask, taken along the line A-A in FIG. 1;

FIG. 3 is a schematic partially-sectional diagram of a pattern area in the embodiment of FIG. 1;

FIG. 4 is a schematic side diagram of the shape of the warping sub-mask, taken along the line B-B in FIG. 1 in an embodiment of the present invention;

FIG. 5 is a schematic side diagram of the shape of the warping sub-mask, taken along the line B-B in FIG. 1 in another embodiment of the present invention; and

FIG. 6 is a flow chart of a method for evaluating an evaporation mask in an embodiment of the present invention.

### DETAILED DESCRIPTION OF PREFERRED EMBODIMENTS

Terms used in the description of the embodiments of the present invention, for example, orientation or position relation such as “above” and “below” are described according to the orientation or position relation shown in the drawings. The above terms are used for facilitating description of the present invention rather than limiting the present invention, i.e., indicating or implying that the mentioned elements have to have specific orientations and to be configured in the specific orientations. In addition, terms such as “first” and “second” involved in the description or claims are merely used for naming the elements or distinguishing different embodiments or ranges rather than limiting the upper limit or lower limit of the quantity of the elements.

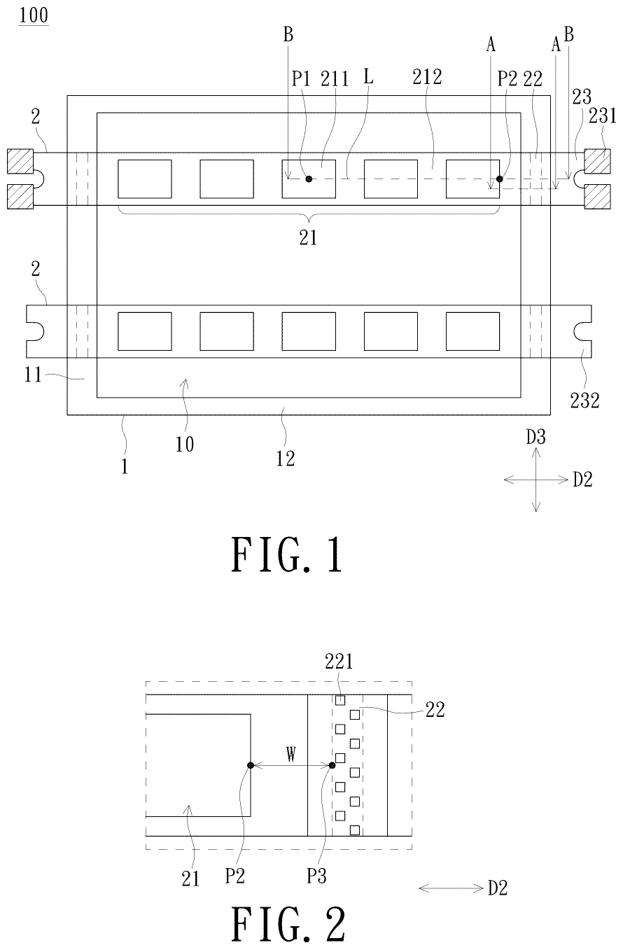

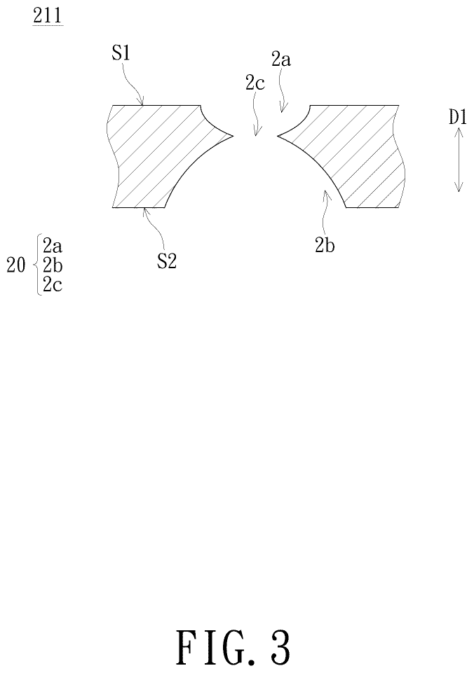

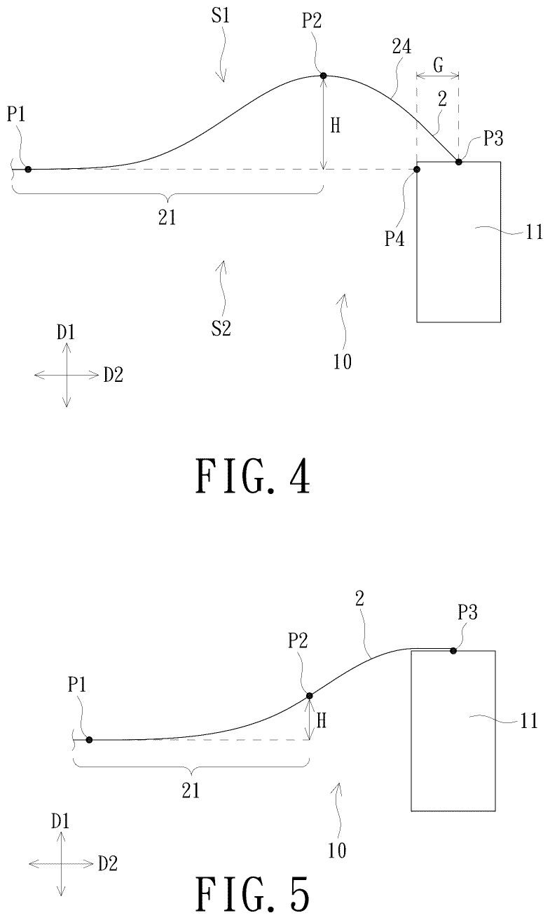

FIG. 1 is a schematic top diagram of an evaporation mask in an embodiment of the present invention. FIG. 2 is a schematic partially enlarged diagram of the evaporation mask, taken along the line A-A in FIG. 1. FIG. 3 is a schematic partially-sectional diagram of a pattern area in the embodiment of FIG. 1. FIG. 4 is a schematic side diagram of the shape of the warping sub-mask, taken along the line B-B in FIG. 1 in an embodiment of the present invention. Assemblies in the figures all are schematic and are not drawn at actual proportions, and only a part of the sub-mask is drawn in FIG. 4.

As shown in FIG. 1, an evaporation mask 100 in the embodiment includes an outer frame 1 and a sub-mask 2. The outer frame 1 is provided with an opening 10 and both sides of the opening 10 are provided with two opposite positioning side edges 11. The sub-mask 2 is adapted to be connected to the outer frame 1 and is provided with a pattern area 21 and two fixed areas 22. The pattern area 21 is located at a center of the sub-mask 2. The fixed areas 22 are located on two opposite sides of the pattern area 21 and are adapted to be respectively connected to different positioning side edges 11 when the sub-mask 2 is connected to the outer frame 1. A surface of the sub-mask 2 is provided with a first datum point P1 and a second datum point P2; the first datum point P1 is located at a center of the pattern area 21; the second datum point P2 is located at an edge, close to one of the fixed areas 22, of the pattern area 21; and a first distance H between the first datum point P1 and the second datum point P2 is less than or equal to 200 μm in a thickness direction D1 of the sub-mask 2.

Specifically speaking, as shown in FIG. 1, in the embodiment, the evaporation mask 100 includes, for example, an outer frame 1 and a plurality of sub-masks 2 (two sub-masks 2 are drawn in FIG. 1, and the quantity of the sub-masks is only schematic and is not limited thereto). The outer frame 1 is, for example, rectangular. Besides the positioning side edges 11, the outer frame is further provided with connecting arms 12 connected between the two positioning side edges 11, and the connecting arms 12 and the positioning side edges 11 jointly encircle the opening 10. There is no limitation on a material of the outer frame 1, and for example, the material is an existing material. The sub-mask 2 is, for example, a rectangular plate. Specifically speaking, the length of the sub-mask 2 is, for example, between 150 mm and 500 mm. The thickness is, for example, between 10 μm and 150 μm. Its width can be set as needed. In a width direction D3, the width of the sub-mask 2 is, for example, less than the width of the opening 10. The material of the sub-mask 2 is, for example, a ferro-nickel alloy, but is not limited thereto.

As shown in FIG. 1, in the embodiment, the sub-mask 2, for example, further includes clamping regions 23 located at both ends. The above-mentioned fixed regions 22 are located between the pattern region 21 and the clamping regions 23, but detailed patterns are not limited thereto. The pattern region 21 is a region covering the glass substrate (not shown in the drawing) to form a light-emitting pattern (not shown in the drawing) in the evaporation process. In the embodiment, there are, for example, 5 pattern areas 211 and an interval section 212 located between the two pattern areas 211 in the pattern region 21, but the embodiment is not limited thereto.

As shown in FIG. 2 and FIG. 3, a plurality of through-holes 20 passing through the sub-mask 2 in the thickness direction D1 of the sub-mask 2 are formed in each pattern area 211. The through-holes 20 are formed, for example, by a wet etching method, but the embodiment is not limited thereto. As shown in FIG. 3, in the thickness direction D1, the through-hole 20 includes, for example, a first opening 2a located in a back surface S1, a second opening 2b located in an evaporation surface S2, and a neck opening 2c located between the first opening 2a and the second opening 2b. An opening sectional area of the second opening 2b is, for example, greater than an opening sectional area of the first opening 2a and the neck opening 2c. The opening sectional area of the neck opening 2c is, for example, smaller than the opening sectional area of the first opening 2a. However, the detailed shape of the through-hole 20 is not limited thereto.

As shown in FIG. 1, the clamping region 23 is a region where a clamp 231 temporarily fixing the position of the sub-mask 2 temporarily clamps the sub-mask 2 in the manufacturing process where the sub-mask 2 is connected to the outer frame 1. Specifically speaking, in the embodiment, two extension portions 232 separated from each other are respectively arranged, for example, in each clamping region 23 (each end of the sub-mask 2). The extension portions 232 are adapted to be clamped temporarily by the clamp 231 during use, but are not limited thereto.

The fixed region 22 is a region where the sub-mask 2 connected to the outer frame 1 is welded and fixed. In the embodiment, the sub-mask 2 is, for example, but not limited to, fixed to the outer frame 1 (the positioning side edges 11) by way of spot welding. As shown in FIG. 2, specifically speaking, the sub-mask 2 is, for example, connected to the outer frame 1 in a manner that a plurality of welding points 221 are jointly fixed. The patterns of the welding points 221 are, for example, but not limited to, arranged in two lines. The two lines are parallel to each other and are perpendicular to an extension direction D2 of the sub-mask 2. The welding points 221 are separated from one another, and the welding points 221 between two adjacent lines are staggered to one another. The shape and range of the fixed region 22 are encircled by the welding points 221.

As shown in FIGS. 1-4, in the embodiment, in the extension direction D2, an edge at one side, close to the pattern region 21, of the fixed area 22 is, for example, provided with a third datum point P3, and a side (the opening 10 side) close to the pattern region 21 of the positioning side edge 11 is, for example, provided with a fourth datum point 4. In the thickness direction D1, there are no limitations on positional relationships among the first datum point P1, the second datum point P2, the third datum point P3 and the fourth datum point P4. There is, for example, a gap G between the third datum point P3 and the fourth datum point P4, in the extension direction D2. In other words, when the sub-mask 2 is connected to the outer frame 1, the fixed area 22 will be away from the edge (the opening 10) of the positioning side 11. The detailed welding pattern is not limited by the above example.

As shown in FIG. 4, the surface of the sub-mask 2 is divided into the evaporation surface S2 and the back surface S1 in the thickness direction D1, and the evaporation surface S2 is the surface at one side facing an evaporation source during use. The back surface S1 is the surface at one side facing the glass substrate during use. As shown in FIG. 1 and FIG. 4, when the sub-mask 2 is fixed to the outer frame 1, the sub-mask 2 covers the opening 10 and is in contact with the outer frame 1 with the evaporation surface S2. The pattern region 21 covers the front of the opening 10 and the clamping region 23 extends out of the positioning side edge 11 of the outer frame 1.

As shown in FIGS. 1-4, in the embodiment, the first datum point P1 and the second datum point P2 are, for example, located on a same line L in the extension direction D2 of the sub-mask 2. The line L is, for example, located at the center of the sub-mask 2 in the width direction D3 of the sub-mask 2, but is not limited thereto. In addition, although only the second datum point 2 located on the right side of the pattern area 21 in FIG. 1 is drawn in FIG. 2 and FIG. 4, it should be understood that during actual measurement, the second datum point P2 which is on the left side of the pattern region 21 and is not drawn in FIG. 1 should also be measured.

During the actual measurement, for example, a non-contact measuring instrument can be used to measure the first datum point P1 and the second datum point P2 located on the back surface S1. Because the first datum point P1 or the second datum point P2 may be just located at the through-hole 20, when determining a reading number, the first datum point P1 and the second datum point P2 can be deviated from the lines L (for example, slightly deviated in the width direction D3) in the extension direction D2 to avoid the opening position of the through-hole 20 or be slightly deviated from the edge or center of the pattern region 21 in the extension direction D2.

The first datum point P1 and the second datum point P2 can be located on the evaporation surface S2 or the back surface S1 (shown in FIG. 3) of the sub-mask 2. However, because it is needed to prevent a material thickness of the sub-mask 2 from affecting a measuring result during measurement, the first datum point P1 and the second datum point P2 shall be located on the evaporation surface S2 or the back surface S1 at the same time. In addition, as shown in FIG. 4, owing to the influence of the weight of the sub-mask 2 itself, the first datum point P1 is, for example, lower than the second datum point P2 in the thickness direction D1 (the vertical direction in FIG. 2) according to the arrangement direction of the evaporation mask 100 during measurement, but is not limited thereto.

As shown in FIGS. 1-4, in the embodiment, a protruding section 24 is formed between the pattern region 21 and the welding region on the sub-mask 2. The protruding section 24 protrudes, for example, toward the back surface S1 in the thickness direction D1, but is not limited thereto. The protruding section 24 is provided with a vertex (not marked in the drawings) in the thickness direction D1, and is, for example, located at the position of the second datum point P2, but is not limited thereto. In other words, in other embodiments, the vertex can be, for example, located between the second datum point P2 and the fourth datum point P4 or other intervals according to a welding result or the self-weight and structure of the sub-mask 2. FIG. 5 is a schematic side diagram of the shape of the warping sub-mask, taken along the line B-B in FIG. 1 in another embodiment of the present invention. It can be known from FIG. 5 that in other embodiments, owing to the welding result or different connecting modes, the protruding section 24 is not necessarily formed on the sub-mask 2.

As shown in FIG. 2 and FIG. 4, in the embodiment, in the interval direction (the same as the extension direction D2) perpendicular to the thickness direction D1, there is a second distance W between the second datum point P2 and the adjacent fixed area 22, and the second distance W is, for example, greater than or equal to 20 mm. A situation, in which the evaporation effect is affected as the flatness (relative to the horizontal direction in FIG. 4) of the pattern region 21 is affected by the protruding section 24, can be avoided.

It can be known from the above description that for the evaporation mask 100 in the embodiment, because the height difference between the center and the edge of the pattern area 21 subjected to welding and gravity is still smaller than a fixed value, when the glass substrate is evaporated, the mask fits the surface of the glass substrate as far as possible, so that the problem of diffused evaporation generated by separation of the evaporation mask 100 and the glass substrate is avoided.

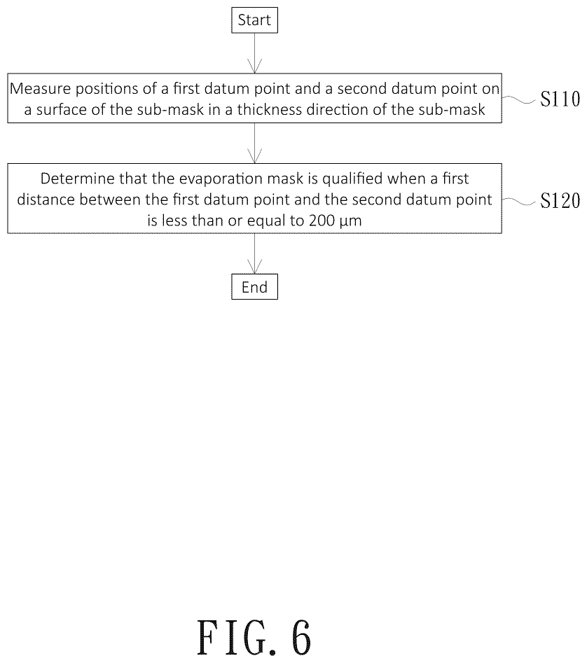

FIG. 6 is a flow chart of a method for evaluating an evaporation mask in an embodiment of the present invention. Referring to FIG. 6, the method in the embodiment includes the following steps:

S110 (referring to FIG. 1): measuring positions of a first datum point P1 and a second datum point P2 on a surface of the sub-mask 2 in the thickness direction D1 of the sub-mask 2; and

S120 (referring to FIG. 4 or 5): determining that the evaporation mask 100 is qualified when a first distance H between the first datum point P1 and the second datum point P2 is less than or equal to 200 μm.

It can be known from the above description that for the method for evaluating an evaporation mask in the embodiment, to evaluate the qualified evaporation mask 100, because the height difference between the center and the edge of the pattern area subjected to welding and gravity is still smaller than a fixed value, when the glass substrate is evaporated, the mask fits the surface of the glass substrate as far as possible, so that the problem of diffused evaporation generated by separation of the evaporation mask and the glass substrate is avoided.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An evaporation mask, comprising:
an outer frame, provided with an opening, wherein both sides of the opening are provided with two opposite positioning side edges; and
a sub-mask, adapted to be connected to the outer frame and provided with a pattern area and two fixed areas, wherein the pattern area is located at a center of the sub-mask, and the two fixed areas are located on two opposite sides of the pattern area and are adapted to be respectively connected to the two positioning side edges when the sub-mask is connected to the outer frame; and
wherein a surface of the sub-mask is provided with a first datum point and a second datum point, the first datum point is located at a center of the pattern area, the second datum point is located at an edge, close to one of the two fixed areas, of the pattern area, and a first distance between the first datum point and the second datum point is less than or equal to 200 μm in a thickness direction of the sub-mask.

2. The evaporation mask according to claim 1, wherein there is a second distance between the second datum point and the adjacent fixed area in an interval direction perpendicular to the thickness direction, and the second distance is greater than or equal to 20 mm.

3. The evaporation mask according to claim 1, wherein a protruding section is formed on the sub-mask, and the protruding section is located between the first datum point and the fixed area.

4. The evaporation mask according to claim 1, wherein there is a plurality of welding points between the sub-mask and the outer frame, and the fixed area is encircled by the welding points.

5. The evaporation mask according to claim 4, wherein the welding points are arranged as a plurality of straight lines, and the welding points in different lines are staggered.

6. The evaporation mask according to claim 1, wherein a length of the sub-mask is between 150 mm and 500 mm.

7. The evaporation mask according to claim 1, wherein the pattern area is provided with a plurality of through-holes passing through the sub-mask in a thickness direction of the sub-mask.

8. The evaporation mask according to claim 7, wherein in the thickness direction, the surface is at least one of an evaporation surface and a back surface, the through-holes comprise a first opening located in the back surface, a second opening located in the evaporation surface, and a neck opening located between the first opening and the second opening, and an opening sectional area of the second opening is larger than an opening sectional area of the neck opening.

9. The evaporation mask according to claim 7, wherein the first datum point and the second datum point are located next to the through-holes.

10. A method for evaluating an evaporation mask, wherein the evaporation mask comprises an outer frame and a sub-mask, the outer frame is provided with an opening, both sides of the opening are provided with two opposite positioning side edges, the sub-mask is adapted to be connected to the outer frame and is provided with a pattern area and two fixed areas, the pattern area is located at a center of the sub-mask, the two fixed areas are located on two opposite sides of the pattern area and are adapted to be respectively connected to the two positioning side edges when the sub-mask is connected to the outer frame; and the method comprises:
measuring positions of a first datum point and a second datum point on a surface of the sub-mask in a thickness direction of the sub-mask, wherein the first datum point is located at a center of the pattern area, and the second datum point is located at an edge, close to one of the fixed areas, of the pattern area; and
determining that the evaporation mask is qualified when a first distance between the first datum point and the second datum point is less than or equal to 200 μm.
